(19) United States
(12) Patent Application Publication
(10) Pub. No.: US 2018/0025889 A1
(43) Pub. Date: Jan. 25, 2018

(54) NONTHERMAL PLASMA SYNTHESIS

(71) Applicant: Regents of the University of Minnesota, Minneapolis, MN (US)

(72) Inventors: Katharine Hunter, St Paul, MN (US); Uwe Richard Kortshagen, Roseville, MN (US)

(21) Appl. No.: 15/648,843

(22) Filed: Jul. 13, 2017

Related U.S. Application Data
(60) Provisional application No. 62/365,692, filed on Jul. 22, 2016.

(51) Int. Cl. H01J 37/32; B82B 3/00

(52) U.S. Cl. CPC H01J 37/32009; B82B 3/0033; B82B 3/0019

(57) ABSTRACT

An apparatus may include a nonthermal plasma reactor vessel, a gaseous core precursor inlet, a gaseous shell precursor inlet, and a plasma source. The reactor vessel may include a core formation region and a shell formation region downstream of the core formation region. The gaseous core precursor inlet may be upstream of the core formation region and configured to introduce gaseous core precursors to the reactor vessel. The gaseous shell precursor inlet may be downstream of the core formation region, upstream of the shell formation region, and configured to introduce gaseous shell precursors to the reactor vessel. The plasma source may be configured to produce a plasma in the core formation region and the shell formation region. The gaseous core precursors may form negatively-charged core nanoparticles in the core formation region. The gaseous shell precursors may form shells on the core nanoparticles in the shell formation region.

This application claims the benefit of U.S. Provisional Application No. 62/365,692, filed Jul. 22, 2016, the entire content of which is incorporated by reference herein.

### GOVERNMENT RIGHTS

This invention was made with government support under contract number DMR-1420013 awarded by the National Science Foundation and DE-AC52-06NA25396 awarded by the Department of Energy. The government has certain rights in the invention.

### TECHNICAL FIELD

The disclosure relates to techniques for forming core/shell nanoparticles.

### BACKGROUND

Nanoparticles are nanometer scale particles that exhibit a variety of properties. Nanoparticles have a wide range of applications, including solar energy conversion, optoelectronic devices, molecular imaging, and ultrasensitive detection. For example, semiconducting nanocrystals are nanoparticles that may exhibit size-dependent bandgaps. The size of the semiconducting nanocrystals can be controlled to fine tune their optoelectronic properties. These semiconducting nanocrystals often have a core material surrounded by a shell material. Core-shell semiconducting nanocrystals may be used as quantum dots in biomedical imaging. The quantum dot may have a narrowly-tailored fluorescence and a high quantum yield. The quantum dot may enter a cell and remain in the cell for an extended period of time. The cell's movement and growth may be tracked using fluorescence. The fluorescent emission wavelengths of the quantum dots may be calibrated based on the size of the quantum dots.

As another example, core-shell metal nanoparticles with a metal core and a metal shell may be used in catalysis. The metal shell may contain a number of active sites, and electronic interactions between the metal shell and metal core may create certain catalytic properties. Often, one or both of the metal shell and core contain a precious metal, such as platinum or palladium. As yet another example, silica core and gold shell nanoparticles may be used for cancer imaging and treatment. The plasmonic resonance absorption spectra may be controlled by the gold shell coverage.

### SUMMARY

In some examples, the disclosure describes a method that may include powering, using a plasma source, a nonthermal plasma reactor to form a plasma in a core formation region and a shell formation region of the nonthermal plasma reactor. The shell formation region may be downstream of the core formation region. The method may further include introducing, upstream of the core formation region, gaseous core precursors. The gaseous core precursors may form negatively-charged core nanoparticles from the gaseous core precursors in the core formation region of the nonthermal plasma reactor. The method may further include introducing, to the plasma downstream of the core formation region, gaseous shell precursors. The gaseous shell precursors may form shells on the core nanoparticles in the shell formation region of the nonthermal plasma reactor.

In another example, the disclosure describes an apparatus that may include a nonthermal plasma reactor vessel, a gaseous core precursor inlet, a gaseous shell precursor inlet, and a plasma source. The nonthermal plasma reactor vessel may include a core formation region and a shell formation region downstream of the core formation region. The gaseous core precursor inlet may be upstream of the core formation region. The gaseous core precursor inlet may be configured to introduce gaseous core precursors to the reactor vessel. The gaseous shell precursor inlet may be downstream of the core formation region and upstream of the shell formation region. The gaseous shell precursor inlet may be configured to introduce gaseous shell precursors to the reactor vessel. The plasma source may be configured to produce a plasma in the core formation region and the shell formation region. The gaseous core precursors may form negatively-charged core nanoparticles from the gaseous core precursors in the core formation region of the reactor vessel. The gaseous shell precursors may form shells on the core nanoparticles in the shell formation region of the reactor vessel.

In another example, the disclosure describes a system that includes a controller. The controller may control a plasma source to power a nonthermal plasma reactor to form a plasma in a core formation region and a shell formation region of the nonthermal plasma reactor. The shell formation region may be downstream of the core formation region. The controller may be further configured to control a gaseous core precursor inlet to introduce gaseous core precursors to the nonthermal plasma reactor. The gaseous core precursor inlet may be upstream of the core formation region. The gaseous core precursors may form negatively-charged core nanoparticles from the gaseous core precursors in the core formation region of the nonthermal plasma reactor. The controller may be further configured to control a gaseous shell precursor inlet to introduce gaseous shell precursors to the nonthermal plasma reactor. The gaseous shell precursor inlet may be downstream of the core formation region and upstream of the shell formation region. The gaseous shell precursors may form shell on the core nanoparticles in the shell formation region of the nonthermal plasma reactor.

In another example, the disclosure describes a computer-readable storage medium storing instructions that, when executed, may cause a processor to power, using a plasma source, a nonthermal plasma reactor to form a plasma in a core formation region and a shell formation region of the nonthermal plasma reactor. The shell formation region may be downstream of the core formation region. The instructions may also cause the processor to introduce, upstream of the core formation region, gaseous core precursors. The gaseous core precursors may form negatively-charged core nanoparticles from the gaseous core precursors in the core formation region of the nonthermal plasma reactor. The instruction may also cause the processor to introduce, to the plasma downstream of the core formation region, gaseous shell precursors. The gaseous shell precursors may form shell on the core nanoparticles in the shell formation region of the nonthermal plasma reactor.

The details of one or more examples are set forth in the accompanying drawings and the description below. Other features, objects, and advantages of the disclosure will be apparent from the description and drawings, and from the claims.

### BRIEF DESCRIPTION OF DRAWINGS

FIG. 1 is a conceptual and schematic block diagram illustrating an example apparatus for manufacturing core/shell nanoparticles using a nonthermal plasma reactor.

FIG. 2 is a flow diagram illustrating an example technique for manufacturing core/shell nanoparticles using a nonthermal plasma reactor.

FIG. 3 is a conceptual cross-sectional diagram illustrating an example system for manufacturing Ge/Si nanocrystals using a nonthermal plasma reactor.

FIG. 4 shows EDX spectrum images of the elemental distribution of constituent particles in the Ge/Si core/shell nanocrystals.

FIG. 5 shows STEM-HAADF images and corresponding size distribution graphs of Ge/Si nanocrystals synthesized at 0, 0.01, 0.02, and 0.05 sccm SiH₄ flowrates in the gaseous shell feed, respectively.

FIG. 6 is a graph of raw XRD data of Ge/Si core/shell nanocrystals synthesized with an increasing percentage of SiH₄ in the gaseous shell feed.

FIG. 7 is a graph of Ge/Si nanocrystal composition and lattice constant for various feed rates of SiH₄.

FIG. 8 is an inset graph of absorption transition as a function of compressive strain induced by increasing shell thickness for Ge nanocrystal cores, and an outset graph of a change in absorption spectra for various layers of shell thickness of Ge/Si nanocrystals.

FIG. 9 is a graph of wavenumber and mid-infrared absorbance for Ge nanocrystals, Ge/Si partially coated nanocrystals, Ge/Si fully coated nanocrystals, and Si nanocrystals.

### DETAILED DESCRIPTION

The disclosure describes systems and techniques for manufacturing core/shell nanoparticles from gaseous precursors using a nonthermal plasma reactor.

Core/shell nanoparticles produced from gaseous precursors using a nonthermal plasma reactor may include a core formed from gaseous core precursors and a shell formed from gaseous shell precursors. A core/shell nanoparticle may have properties derived from each of its components, as well as properties resulting from the interactions between its components. For example, nanoparticles such as Ge/Si nanocrystals may have a Ge core and a Si shell. Due to a large valence band offset between Ge and Si, holes may be confined to the Ge core and electrons may be localized in the Si shell near the core/shell interface. The Ge/Si nanocrystals may further include boron or phosphorus dopant precursors. Such Si-capped Ge core/shell nanocrystals may be used for improved MOSFET memory structures, photovoltaic devices, and thermoelectrics. Core/shell nanoparticles may also have properties derived from the conditions in which the nanoparticles were fabricated. For example, nanoparticles heated above one or more of the crystallization temperatures of the shell or core components may form nanocrystals.

An apparatus for manufacturing core/shell nanoparticles may include a nonthermal plasma reactor vessel, a gaseous core precursor inlet, a gaseous shell precursor inlet, and a plasma source. The nonthermal plasma reactor vessel may include a core formation region and a shell formation region downstream of the core formation region. The plasma source may produce a plasma in the core and shell formation regions.

The gaseous core precursor inlet may introduce gaseous core precursors to the reactor vessel upstream of the core formation region. In the core formation region, the gaseous core precursors nucleate and form negatively-charged core nanoparticles from the gaseous core precursors. The negative charge on the core nanoparticles may suppress agglomeration of the core nanoparticles and maintain substantially individual dispersion of core nanoparticles (e.g., dispersion of most or nearly all of the core nanoparticles as individual nanoparticles). Unlike solution-phase formation, core nanoparticles formed from the gas phase may not require prior functionalization with organic ligands for colloidal stability of the core nanoparticles.

The gaseous shell precursor inlet may introduce gaseous shell precursors to the reactor vessel downstream of the core formation region and upstream of the shell formation region. In the shell formation region, the gaseous shell precursors form shells on the core nanoparticles. Low plasma density in the shell formation region may reduce radical generation and favor heterogeneous shell growth over homogeneous nucleation of shells on the core nanoparticles.

In some examples, the apparatus may include a nanoparticle collection unit downstream of the shell formation region for collecting core/shell nanoparticles. In some examples, other gases may be introduced to the reactor vessel as part of a gaseous core feed, a gaseous shell feed, or a separate feed. Inert or carrier gases may be introduced along with the gaseous core and shell precursors to control the concentration of the gaseous core and shell precursors, while scavenger gases may be introduced to scavenge other gases or radicals. Gaseous dopant precursors may be added during core or shell formation to imbue certain properties in the resulting core/shell nanoparticles.

In some examples, core/shell nanoparticles produced from gaseous precursors by a nonthermal plasma reactor may have a wide variety of core, shell, and dopant materials. In some examples, core/shell nanoparticles may include high melting point materials utilizing high synthesis temperatures. In other examples, core/shell nanoparticles may be heated past at least one of the core or shell component crystallization temperatures to core/shell nanoparticles that include a crystalline core, a crystalline shell, or both.

In some examples, the core/shell nanoparticles formed using the techniques and reactor design described herein may have high size uniformity and narrow size distributions due to reduced agglomeration during core nanoparticle formation. In some examples, core/shell nanoparticles may be produced efficiently with higher precursor utilization and fewer stability additives than liquid precursor techniques.

Core/shell nanoparticles produced using the systems and techniques of this disclosure may have a variety of useful properties, such as size-tunable optical properties, high electrical conductivities in thin films of interacting nanoparticles, and formation of multiple excitons in response to absorption from a photon. These core/shell nanoparticles may be used for a variety of applications including, but not limited to: electronics applications such as semiconductor quantum dots and quantum dot-based light sources; biomedical applications such as bioimaging, biosensing, and photothermal medical therapies; and energy applications such as quantum dot solar cells, photonically-enhanced solar cells, and hot electron generation for photocatalysis and photovoltaics.

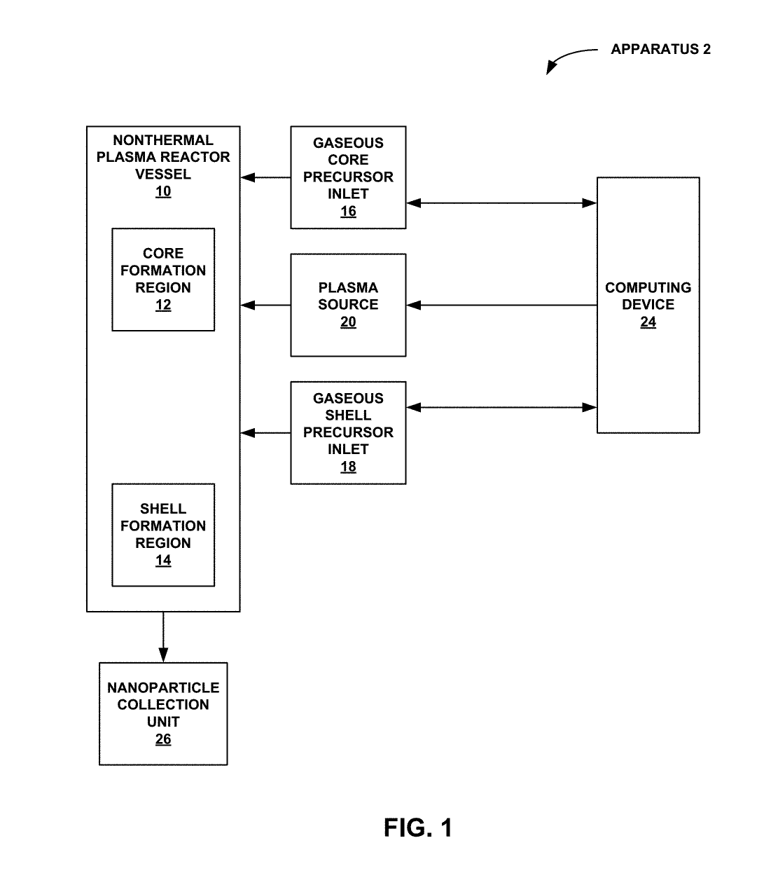

FIG. 1 is a conceptual and schematic block diagram illustrating an example apparatus 2 for manufacturing core/shell nanoparticles from a gaseous core precursor and a gaseous shell precursor using a nonthermal plasma reactor. Apparatus 2 includes nonthermal plasma reactor vessel 10, gaseous core precursor inlet 16, gaseous shell precursor inlet 18, and plasma source 20. In some examples, as shown in FIG. 1, apparatus 2 also may optionally include a computing device 24, a nanoparticle collection unit 26, or both.

Apparatus 2 includes nonthermal plasma reactor vessel 10. Reactor vessel 10 may be configured to house and facilitate nonthermal plasma synthesis of core/shell nanoparticles from a gaseous core precursor and a gaseous shell precursor. In some examples, reactor vessel 10 may be configured as a flow through reactor where the bulk contents of reactor vessel 10 move in substantially a single direction (e.g., a single direction or nearly a single direction) through the length of reactor vessel 10. In some examples, reactor vessel 10 may include a single vessel. In other examples, reactor vessel 10 may include multiple vessels coupled together. For example, a first vessel may form a first stage of reactor vessel 10, such as a core formation region 12, while a second vessel may form a second stage of reactor vessel 10, such as a shell formation region 14. In some examples, reactor vessel 10 may include temperature sensing and control equipment, pressure sensing and control equipment, and flow sensing and control equipment, such as heaters, coolers, temperature gauges, pressure gauges, flow meters, purge valves, and outlet valves. In some examples, reactor vessel 10 may be configured for use with a pressure between about 1 Pa and about 10⁶ Pa. In some examples, reactor vessel 10 may be configured for use at a temperature between about 300 K and about 1000 K. In other examples, core/shell nanoparticles may include core/shell nanocrystals, and reactor vessel 10 may be configured for use with a plasma temperature of at least a crystallization temperature of the core/shell nanocrystals.

Apparatus 2 may also include plasma source 20 configured to produce a plasma in core formation region 12 and shell formation region 14 of reactor vessel 10. The plasma may be a nonthermal plasma formed by at least some of the gaseous core precursors in core formation region 12 and at least some of the gaseous shell precursors in shell formation region 14. For example, the gaseous core precursors, the gaseous shell precursors, or both may include both gaseous species that are precursors to the nanoparticle core and shell, respectively, along with one or more gaseous species that form the plasma when exposed to the energy produced by plasma source 20. In some examples, the plasma may be produced to break down or activate the gaseous core precursors and the gaseous shell precursors.

Plasma source 20 may be positioned at any reactor vessel 10 location with respect to gaseous core precursor inlet 16 and gaseous core precursor inlet 18 so as to provide a plasma electron density profile appropriate for core and shell growth in core formation region 12 and shell formation region 14, respectively. The plasma electron density profile may be a spatial profile of electron density that varies across a radius and/or axis of a reactor. An appropriate plasma electron density profile may depend, for example, on factors such as: composition and properties of precursor gases such as radical formation and precursor flow rate; power source type and coupling; nanoparticle properties such as melting point, diffusion coefficients, and crystallization temperature; and the like.

Plasma source 20 may include a means for applying an electric field to reactor vessel 10. In some examples, plasma source 20 may include one or more microwave plasma tubes electrically coupled to a power source. In example apparatuses using a microwave plasma source, the plasma tubes may be positioned downstream of gaseous core precursor inlet 16 and upstream of gaseous shell precursor inlet 18. In some examples, plasma source 20 may include an induction coil electrically coupled to a power source. In example apparatuses using induction, the induction coil may be wrapped around reactor vessel 10 and positioned downstream of gaseous core precursor inlet 16. In some examples, plasma source 20 may include one or more electrodes electrically coupled to a power source. The power source may power the electrodes to create a plasma in reactor vessel 10. The electrodes may include, but are not limited to, copper ring electrodes and wire plate electrodes. The power source may include, but is not limited to, radiofrequency (RF), alternating current (AC), and direct current (DC) power sources. The position of electrodes relative to reactor vessel 10 may vary with the type of power used by the power source and the geometries of the electrodes and reactor vessel 10. In some example apparatuses that utilize an RF power source, the electrodes may be positioned downstream of gaseous core precursor inlet 16 and upstream of gaseous shell precursor inlet 18 to create a plasma upstream and downstream of the electrodes. In some example apparatuses that utilize a DC power source, at least one of the electrodes may be positioned downstream of gaseous core precursor inlet 16 and upstream of gaseous shell precursor inlet 18, and at least one of the electrodes may be positioned downstream of gaseous shell precursor inlet 18 to create a plasma between the electrodes. In some example apparatuses that utilize a ground electrode, the ground electrode may be positioned in reactor vessel 10.

In some examples, plasma source 20 may be selected and configured in one of a variety of configurations to produce a plasma. For example, at low pressures (e.g., between about 1 Pa and about 1000 Pa), plasmas may be produced by a variety of plasma sources in continuous or pulse discharge operation including, but not limited to: DC glow discharges, RF capacitively coupled plasmas, RF inductively coupled plasmas, microwave produced plasmas in microwave resonators, RF and microwave traveling produced plasmas, electron beam produced plasmas, and DC and RF hollow cathode discharges. In other examples, at higher pressures (e.g., between about 1000 Pa and about 10⁶ Pa), plasmas may be produced by a variety of plasma sources in continuous or pulse discharge operation including, but not limited to: DC arc discharges, RF capacitively coupled plasmas, RF inductively coupled plasmas, microwave produced plasmas in microwave resonators, RF and microwave traveling produced plasmas, electron beam produced plasmas, DC and RF hollow cathode discharges, corona discharges, spark discharges, dielectric barrier discharges, atmospheric pressure glow discharges, and gliding arc discharges.

Apparatus 2 may also include gaseous core precursor inlet 16 upstream of core formation region 12. Gaseous core precursor inlet 16 is configured to introduce gaseous core precursors in a gaseous core feed to reactor vessel 10 upstream of core formation region 12. In some examples, gaseous core precursor inlet 16 may include an opening in reactor vessel 10 configured to fluidically couple to a gaseous core precursor conduit (not shown in FIG. 1), such as a pipe, which is fluidically coupled to a gaseous core precursor source (not shown in FIG. 1). In some examples that include process control elements, gaseous core precursor inlet 16 may include one or more control valves configured to control the flow of gaseous core precursors to reactor vessel 10, one or more flow meters configured to measure the flow of gaseous core precursors to reactor vessel 10, or the like. In some examples in which the gaseous core feed includes additional gases, such as core inert gases, carrier gases, dopant precursor gases, or the like, gaseous core precursor inlet 16 may further include one or more control valves configured to control the flow of the additional gases to reactor vessel 10, one or more flow meters configured to measure the flow of the additional gases to reactor vessel 10, or the like. In some examples, the flow rates of gaseous core precursors and additional gases may be controlled so that the gaseous core precursors entering the reactor vessel are at a particular concentration (e.g., volumetric concentration, molar concentration, or mass concentration).

Gaseous core precursor inlet 16 may introduce one or more gaseous precursors to nonthermal plasma reactor vessel 10, and the identity of the one or more gaseous precursor may be selected based on the desired composition of the core of the nanoparticle and the conditions in nonthermal plasma reactor vessel 10. For example, GeCl₄ may be selected as a gaseous core precursor for Ge/Si nanocrystals due to the presence of the Ge core species and the lower toxicity of GeCl₄ to alternatives such as GeH₄. A wide variety of gaseous core precursors may be used including, but not limited to: Group II organometallics, such as dimethyl cadmium; Group III organometallics, such as trimethyl gallium, trimethyl indium, and gallium nitride; Group IV hydrides, such as silanes, germanes, and stannanes; Group IV organometallics, such as organosilanes, organogermanes, and organostannanes; Group IV halides, such as chlorosilanes, chlorogermanes, and chlorostannanes; Group IV aromatics, such as aromatic silanes, aromatic germanes, aromatic stannanes; Group V organometallics, such as trimethyl arsenide; Group VI organometallics, such as diphenyldiselenide; Group IIA, IIA, IVA, VA, IB, IIB, IVB, VB, VIB, VIIB, and VIBB metal carbonyls, halides, and organometallics; metal oxides such as iron oxide; metal nitrides such as titanium nitride; metal sulfides; or ceramic precursors such as silanes. Some specific examples include GeH₄, GeCl₄, SiH₄, and SiCl₄. Other gaseous core precursors that may be used are described in U.S. Pat. No. 7,446,335, entitled PROCESS AND APPARATUS FOR FORMING NANOPARTICLES USING RADIO FREQUENCY PLASMAS, by Kortshagen et al., which is incorporated herein by reference in its entirety.

In some examples, additional gases may be introduced to the reactor vessel 10 through gaseous core precursor inlet 16, including core inert gases such as argon, helium, or the like; carrier gases; scavenging gases such as hydrogen; dopant precursor gases such as aluminum, boron, and phosphorus hydrides, halides, organics, or the like; oxidizing agents such as oxygen, CO₂, NO₂, NO, or the like; and reducing agents such as H₂. For example, gaseous core precursor inlet 16 may introduce an inert gas such as argon to achieve a particular concentration of the gaseous core precursor. In some examples, gaseous core precursor inlet 16 may introduce a gaseous dopant precursor such as boron or phosphorus hydride in, for example, a Ge gaseous core precursor feed to create boron or phosphorus doped Ge/Si semiconductor nanocrystals. In some examples, gaseous core precursor inlet 16 may introduce hydrogen gas to scavenge chlorine gas produced from the decomposition of GeCl₄ in formation of Ge/Si nanocrystals.

Gaseous core precursor inlet 16 may have any of a variety of configurations. In some examples, gaseous core precursor inlet 16 may include one inlet, while in other examples, gaseous core precursor inlet 16 may include multiple inlets. For example, gaseous core precursor inlet 16 may include a plurality (e.g., four) of inlets spaced around the circumference of reactor vessel 10 to evenly distribute the gaseous core precursor. In other examples, gaseous core precursor inlet 16 may include multiple inlets, where each inlet introduces a different gas, such as gaseous core precursors, dopant precursor gas, scavenging gas, reducing/oxidizing gas, or inert gas.

Nonthermal plasma reactor vessel 10 may include core formation region 12 in which gaseous core precursors form negatively-charged core nanoparticles. In some examples, core formation region 12 may be an operational region of reactor vessel 10 in which a majority of core nanoparticles are formed. In some examples, core formation region 12 includes a plasma that includes gaseous core precursors. In some example apparatuses that utilize an RF power source, core formation region 12 may have a portion upstream and a portion downstream of electrodes of plasma source 20. In some example apparatuses that utilize a DC power source, core formation region 12 may be between electrodes of plasma source 20. The gaseous core precursors may form core nanoparticles in the core formation region 12 by a variety of stages and mechanisms, including core nanoparticle seeding, core nanoparticle nucleation, core nanoparticle growth, and core nanoparticle crystallization. For example, a gaseous core precursor GeCl₄ may have a core element Ge. Free electrons in the plasma of core formation region 12 may impact the GeCl₄ precursor to initiate dissociation of Ge from Cl, and Ge may subsequently nucleate into negatively-charged Ge nanoparticles. The Ge nanoparticles may grow until the Ge nanoparticle concentration falls below the positive ion density of the plasma. Radical Ge species may deposit onto the Ge nanoparticles. Within core formation region 12, the Ge nanoparticles may be heated above the GE crystallization temperature and crystalize by energetic surface reactions to form Ge core nanocrystals.

Apparatus 2 may also include gaseous shell precursor inlet 18 downstream of core formation region 12 and upstream of shell formation region 14. In some examples, gaseous shell precursor inlet 18 is also downstream of the location of electrodes of plasma source 20, such as when a power source of plasma source 20 provides a RF electrical signal to electrodes to form an RF plasma. In other examples, gaseous shell precursor inlet 18 may be between a first electrode of plasma source 20 and a second electrode of plasma source 20, such as when a power source provides a DC electrical signal to electrodes to form a DC plasma. In some examples, gaseous shell precursor inlet 18 may be located at a position of reactor vessel 10 at which an average plasma density is greater than about 10⁹ electrons per cubic centimeter (cm³). For example, gaseous shell precursor inlet 18 may be located at a position of reactor vessel 10 at which an average plasma density is between about 10⁹ electrons per cm³ and about 10¹¹ electrons per cm³.

Gaseous shell precursor inlet 18 is configured to introduce gaseous shell precursors in a gaseous shell feed to reactor vessel 10. In some examples, gaseous shell precursor inlet 18 may include an opening in reactor vessel 10 configured to fluidically couple to a gaseous shell precursor conduit, such as a pipe (not shown in FIG. 1), which is fluidically coupled to a gaseous core precursor source (not shown in FIG. 1). In some examples that include process control elements, gaseous shell precursor inlet 18 may include one or more control valves configured to control the flow of gaseous shell precursors to reactor vessel 10, one or more flow meters to measure the flow of gaseous shell precursors to reactor vessel 10, or the like. In some examples in which the gaseous shell feed includes additional gases, such as shell inert gases, carrier gases, dopant precursor gases, or the like, gaseous shell precursor inlet 18 may further include one or more control valves configured to control the flow of additional gases to reactor vessel 10, one or more flow meters configured to measure the flow of additional gasses to reactor vessel 10, or the like.

Gaseous shell precursor inlet 18 may introduce one or more gaseous precursors to nonthermal plasma reactor vessel 10, and the identity of the one or more gaseous precursor may be selected based on the desired composition of the shell of the nanoparticle and the conditions in nonthermal plasma reactor vessel 10. A wide variety of gaseous shell precursors may be used including, but not limited to: Group II organometallics, such as dimethyl cadmium; Group III organometallics, such as trimethyl gallium, trimethyl indium, and gallium nitride; Group IV hydrides, such as silanes, germanes, and stannanes; Group IV organometallics, such as organosilanes, organogermanes, and organostannanes; Group IV halides, such as chlorosilanes, chlorogermanes, and chlorostannanes; Group IV aromatics, such as aromatic silanes, aromatic germanes, aromatic stannanes; Group V organometallics, such as trimethyl arsenide; Group VI organometallics, such as diphenyldiselenide; Group IIA, IIA, IVA, VA, IB, IIB, IVB, VB, VIB, VIIB, and VIBB metal carbonyls, halides, and organometallics; metal oxides such as iron oxide; metal nitrides such as titanium nitride; metal sulfides; or ceramic precursors such as silanes. Some specific examples include GeH₄, GeCl₄, SiH₄, and SiCl_{4.} Other gaseous shell precursors that may be used are described in U.S. Pat. No. 7,446,335, entitled PROCESS AND APPARATUS FOR FORMING NANOPARTICLES USING RADIO FREQUENCY PLASMAS, by Kortshagen et al. which is incorporated herein by reference in its entirety. The gaseous shell precursor may be different than the gaseous core precursor.

In some examples, additional gases may be introduced to the reactor vessel 10 through gaseous shell precursor inlet 18 including, but not limited to: shell inert and carrier gases such as argon and helium; scavenging gases such as hydrogen; dopant precursor gases such as aluminum, boron, and phosphorus hydrides, halides, organics, or the like; oxidizing agents such as oxygen, CO₂, NO₂, NO, or the like; and reducing agents such as H₂. For example, an inert gas such as argon may be introduced through gaseous shell precursor inlet 18 to achieve a particular concentration of the gaseous shell precursor in the gaseous shell feed or to achieve a certain amount of turbulence or mixing in the gaseous shell feed. In some examples, inert gases introduced through gaseous core precursor inlet 16 and gaseous shell precursor inlet 18 may be the same inert gas, while in other examples they may be different inert gases. For example, utilizing the same inert gas in the gaseous core feed and the gaseous shell feed may more easily maintain conditions of the reactor vessel 10, such as pressure and concentration. Gaseous shell precursor inlet 18 may introduce a gaseous dopant precursor such as boron or phosphorus hydride in, for example, a GeCl₄ gaseous shell precursor feed to create boron or phosphorus doped Ge/Si semiconductor nanocrystals.

Gaseous shell precursor inlet 18 may have any of a variety of configurations. In some examples, gaseous shell precursor inlet 18 may include one inlet, while in other examples, gaseous shell precursor inlet 18 may include multiple inlets. For example, gaseous shell precursor inlet 18 may include four inlets spaced around the circumference of reactor vessel 10 to more evenly distribute the gaseous shell precursor throughout a cross-sectional area of reactor vessel 10. In other examples, gaseous shell precursor inlet 18 may include multiple inlets, and each inlet may introduce a different gas, such as a gaseous shell precursor, a dopant precursor gas, a scavenging gas, a reducing/oxidizing gas, or an inert gas.

Nonthermal plasma reactor vessel 10 may also include shell formation region 14 downstream of core formation region 12. In shell formation region 14, gaseous shell precursors form shells on the core nanoparticles formed in core formation region 12. In some examples, shell formation region 14 may be an operational region of reactor vessel 10 in which a majority of the shell portion of the core/shell nanoparticles are formed. In some examples, shell formation region 14 includes a plasma that includes gaseous shell precursors, and in other examples the plasma may be visible in shell formation region 14. In some example apparatuses that utilize an RF power source, shell formation region 12 may be substantially downstream of electrodes. In some example apparatuses that utilize a DC power source, shell formation region 12 may be substantially between electrodes.

In some examples, shell formation region 14 has a lower plasma density than core formation region 12, to reduce generation of radicals from the gaseous shell precursors and favor heterogeneous shell growth on the core nanoparticles over homogeneous nucleation of shell particles. In some examples, a reduced plasma density in shell formation region 14 may additionally or alternatively reduce core/shell nanoparticle heating, which may decrease interdiffusion between core and shell and create a more defined core/shell interface. The gaseous shell precursors may form shells on the core nanoparticles in the shell formation region 14 by a variety of stages and mechanisms, including shell deposition and shell crystallization. For example, a gaseous shell precursor SiH₄ may have a core element Si. Free electrons in the plasma of shell formation region 14 may impact the SiH₄ precursor to initiate dissociation of Si from H, and Si may subsequently heterogeneously grow on the surface of the Ge nanoparticles.

In some examples, apparatus 2 may also include nanoparticle collection unit 26 downstream of the shell formation region 14. In some examples, nanoparticle collection unit 26 may be a region of the reactor vessel 10, while in other examples nanoparticle collection unit 26 may be a standalone unit. Nanoparticle collection unit 26 may be configured to collect core/shell nanoparticles from the shell formation region 14 of the reactor vessel 10. In some embodiments, nanoparticle collection unit 26 includes a slotted orifice that produces a nanoparticle beam having core/shell nanoparticles. In some embodiments, nanoparticle collection unit 26 includes a filter.

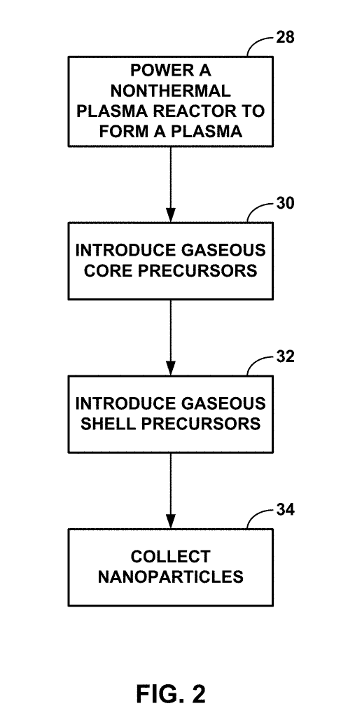

Apparatus 2 may also include computing device 24, which is communicatively coupled to at least gaseous core precursor inlet 16, gaseous shell precursor inlet 18, and plasma source 20. Computing device 24 may include any of a wide range of devices, including processors (e.g., one or more microprocessors, one or more application specific integrated circuits (ASICs), one or more field programmable gate arrays (FPGAs), or the like), servers, desktop computers, notebook (i.e., laptop) computers, tablet computers, set-top boxes, telephone handsets such as so-called “smart” phones, so-called “smart” pads, televisions, cameras, display devices, digital media players, video gaming consoles, video streaming device, cloud computing clusters, and the like. Operation of computing device 24 in apparatus 2 will be described with reference to FIG. 2.

FIG. 2 is a flow diagram illustrating an example technique for manufacturing core/shell nanoparticles from gaseous precursors using a nonthermal plasma reactor. The technique of FIG. 2 will be described with concurrent reference to apparatus 2 of FIG. 1, although one of ordinary skill will understand that the technique of FIG. 2 may be performed by other apparatuses that include more or fewer components, and that apparatus 2 may perform other techniques. The technique of FIG. 2 includes powering, using plasma source 20, a nonthermal plasma reactor to form a plasma in a core formation region 12 and a shell formation region 14 of the nonthermal plasma reactor, wherein the shell formation region 14 is downstream of the core formation region 14 (28).

Plasma source 20 may power the nonthermal plasma reactor to create selected plasma electron densities, plasma electron density distributions, electron temperatures, ion temperatures, and the like, for core and shell formation in core formation region 12 and shell formation region 14, respectively. Example plasma conditions may vary throughout reactor vessel 10 and may include, for example: a free charge carrier density between about 10⁶ and about 10¹⁴ free charge carriers·cm⁻³; an electron temperature between about 0.1 eV and about 10 eV; an ion temperature between about 300 K and about 1000 K; and a pressure of reactor vessel 10 of about 1 Pa to about 10⁶ Pa. For example, the plasma may have a plasma electron density of at least 10¹⁰ cm⁻³ at gaseous core precursor inlet 16. In other examples, plasma source 20 may power the plasma so that the plasma electron density in shell formation region 14 remains below a particular level to reduce formation of excessive shell radicals. In some examples, plasma source 20 may power the nonthermal plasma reactor to create particular temperatures for core and shell formation, such as a crystallization temperature for forming core/shell nanocrystals. For example, plasma source 20 may heat the nanoparticles to a temperature greater than about 700 K, while the gas temperature in the reactor vessel 10 may be less than about 400 K. In other examples, the temperature in shell formation region 14 may be low enough to suppress excess radical shell element formation, such as silane radicals, but high enough to encourage epitaxial shell formation. In systems that utilize process control elements, computing device 24 may control, for example, the power level of plasma source 20.

In some examples, computing device 24 may be configured to control plasma source 20 to produce the plasma in the core formation region 12 and shell formation region 14 of the reactor vessel 10. Computing device 24 may control plasma source 20, for example, to create a plasma having a particular plasma density, such as an average plasma electron density greater than 10¹⁰ electrons·cm⁻³ near the location of gaseous core precursor inlet 16 and greater than 10⁹ electrons·cm⁻³ near the location of gaseous shell precursor inlet 18.

The technique of FIG. 2 may also include introducing, upstream of core formation region 12, gaseous core precursors (30). The gaseous core precursors form negatively-charged core nanoparticles in core formation region 12. The gaseous core precursors may be introduced, for example, by gaseous core precursor inlet 16. The gaseous core precursors may be introduced as part of a gaseous core feed that includes additional gases. In systems that utilize process control elements, computing device 24 may control, for example, a control valve to introduce gaseous core precursors, a flow meter to measure gaseous core feed flow rate, or both.

Introducing gaseous core precursors to reactor vessel 10 may include controlling, such as by computing device 24, one or more of: gaseous core feed flow rate, gaseous core precursor flow rate, additional gas flow rate, and gaseous core precursor concentration. The gaseous core feed flow rate may be controlled to affect the residence time of gaseous core precursors in core formation region 12, which may affect the size of core nanoparticles. For example, as the gaseous core feed flow rate increases, the residence time of core nanoparticles may decrease, which may cause a corresponding decrease in core nanoparticle size such as decreased radius for nanospheres or decreased radius and length for nanowires.

The gaseous core feed flow rate may also be controlled to affect the production rate of core/shell nanoparticles exiting reactor vessel 10. For example, as the gaseous core feed flow rate increases, the production rate of core/shell nanoparticles exiting reactor vessel 10 may increase. The gaseous core precursor concentration in the gaseous core feed may also be controlled to affect the size of core nanoparticles. For example, an increase in the gaseous core precursor concentration of the gaseous core feed may cause an increase in the size of core nanoparticles, as more core particles are available for core growth.

In some examples, the gaseous core precursor concentration in the gaseous core feed may be affected by controlling the flow rate of gaseous core precursors and the flow rate of additional gases into, for example, a conduit transporting the gaseous core feed into reactor vessel 10. In some examples, the flow rate of additional gases and the flow rate of gaseous core precursors may be controlled to increase the gaseous core precursor concentration by, for example, decreasing the additional gas flow rate or increasing the gaseous core precursor flow rate.

In some examples, computing device 24 may be further configured to control gaseous core precursor inlet 16 to introduce gaseous core precursors to the reactor vessel, as described above. For example, computing device 24 may control gaseous core precursor inlet 16 to control the flow rates of the gaseous core precursors or additional gases to result in a particular gaseous core precursor concentration and core nanoparticle size.

The technique of FIG. 2 may also include introducing, to the plasma downstream of core formation region 12, gaseous shell precursors (32). The gaseous shell precursors form shells on the core nanoparticles in shell formation region 14. The gaseous precursors may be introduced, for example, by gaseous shell precursor inlet 18. The gaseous shell precursors may be introduced as part of a gaseous shell feed that includes additional gases. In systems that utilize process control elements, computing device 24 may control, for example, a control valve to introduce gaseous shell precursors, a flow meter to measure the flow rate of the gaseous shell feed, or both.

Introducing gaseous shell precursors to reactor vessel 10 may include controlling, such as by computing device 24, one or more of: gaseous shell feed flow rate, gaseous shell precursor flow rate, additional gas flow rate, and gaseous shell precursor concentration. The gaseous shell feed flow rate may be controlled to affect the residence time of gaseous shell precursors in shell formation region 14, which may affect the thickness of shells on the core nanoparticles. For example, as the gaseous shell feed flow rate increases, the residence time of core nanoparticles may decrease, which may cause a corresponding decrease in shell thickness.

The gaseous shell precursor concentration in the gaseous shell feed may also be controlled to affect the thickness of shells on the core nanoparticles. For example, an increase in the gaseous shell precursor concentration of the gaseous shell feed may cause an increase in the thickness of shells on the core nanoparticles, as more shell radicals are available for epitaxial shell growth. In some examples, the gaseous shell precursor concentration in the gaseous shell feed may be affected by controlling the flow rate of gaseous shell precursors and the flow rate of additional gases into, for example, a conduit transporting the gaseous shell feed into reactor vessel 10. In some examples, the flow rate of additional gases and the flow rate of gaseous shell precursors may be controlled to increase the gaseous shell precursor concentration by, for example, decreasing the additional gas flow rate or increasing the gaseous shell precursor flow rate.

Computing device 24 may be further configured to control gaseous shell precursor inlet 18 to introduce gaseous shell precursors to reactor vessel 10. For example, computing device 24 may control gaseous shell precursor inlet 18 to control the flow rates of the gaseous shell precursor or additional gases to result in a particular gaseous core precursor concentration, such as 2.5% partial pressure of GeCl₄ in a GeCl₄/Ar/H₂ gaseous core feed.

In some examples, computing device 24 may further control gaseous core precursor inlet 16 to introduce dopant precursor gases to reactor vessel 10. For example, computing device 24 may control the flow of boron or phosphorus dopant precursor gases into reactor vessel 10 for semiconducting core/shell Ge/Si nanocrystals.

In some examples, computing device 24 may be further configured to control certain conditions of the reactor vessel 10, such as temperature, pressure, and flow rate. For example, computing device 24 may increase the reactor vessel 10 temperature at the downstream end of the core formation region 12 to assist in heating core nanoparticles above their crystallization temperature to crystallize the core nanoparticles.

In some examples, the technique of FIG. 2 may also include collecting nanoparticles downstream of shell formation region 14 (34) with nanoparticle collection unit 26. In some examples, collecting nanoparticles may include forming a beam of nanoparticles and depositing the nanoparticles on a substrate to form a thin film, such as a printed circuit board substrate. Forming a beam of nanoparticles may include directing nanoparticles through a slotted orifice in nanoparticle collection unit 26. In other examples, collecting nanoparticles may include directing nanoparticles through a filter. In other examples, nanoparticles may be directly mixed into a solvent, for example, to create an ink.

### EXAMPLES

Nonthermal plasmas may provide a reaction environment well-suited for the gas-phase growth of core/shell nanoparticles. Negative-charging of core nanoparticles in the plasma may suppress coagulation, which may keep nanoparticles substantially singly dispersed, so that the shell growth may occur around isolated particles rather than agglomerates. In-flight selective heating of nanoparticles may allow for thicker, high-quality epitaxial shells, as the critical thickness for planar epitaxial growth may increase with temperature. Low plasma density in the shell formation region may limit the generation rate of radicals (e.g., silane radicals) and favor heterogeneous growth over homogeneous nucleation of shells on core nanoparticles. Gas-phase synthesis of core/shell nanoparticles may be substantially indiscriminate of the desired material.

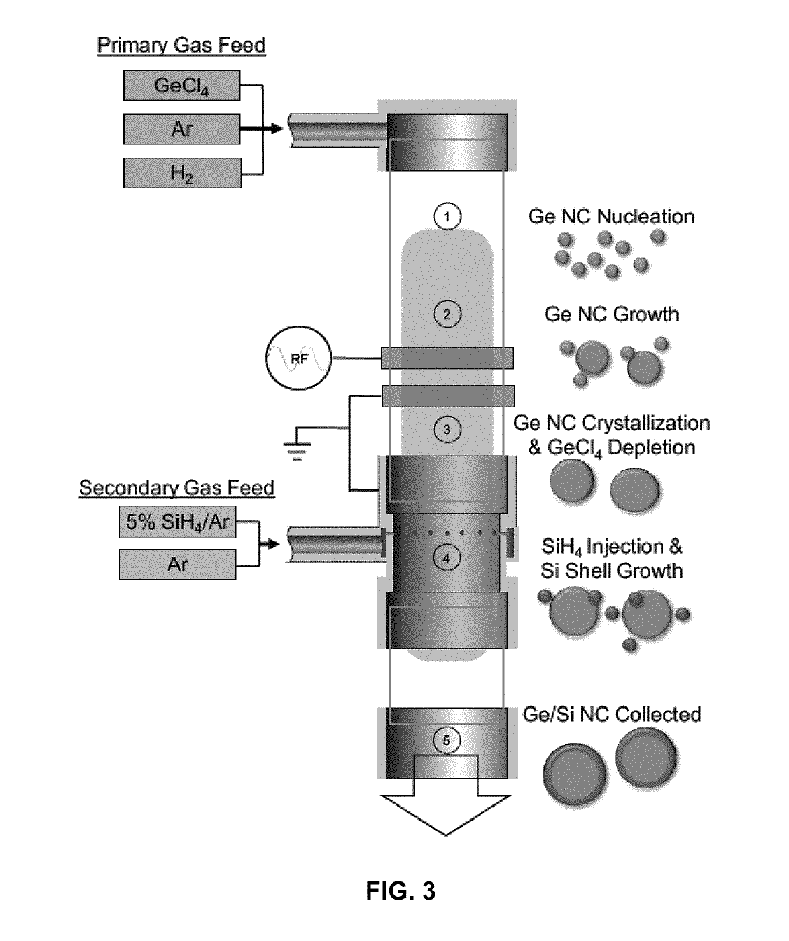

FIG. 3 is a conceptual cross-sectional diagram illustrating an example system for manufacturing core-shell nanoparticles, such as Ge/Si nanocrystals, using a nonthermal plasma reactor. Although FIG. 3 is illustrated as being used to form Ge/Si nanocrystals, the system of FIG. 3 may be modified to be used to form other core/shell nanoparticles by using different precursor gases, and, optionally, different inert gases, scavenger gases, dopant precursor gases, reactor conditions (e.g. plasma electron density, electron temperature), or the like. Ge nanoparticle nucleation and growth occurred in a diffuse plasma above the ring electrodes (e.g., regions 1 and 2 of FIG. 3). In this phase, as the particles grew, the particle concentration eventually dropped below the positive ion density and the Ge nanoparticles averaged at least one elementary charge per nanoparticle. This unipolar negative charging of the nanoparticles in the nonthermal plasma may have suppressed nanoparticle coagulation.

In a bright plasma discharge below the ring electrodes, the Ge nanoparticles were heated above their crystallization temperature by energetic surface reactions. In this region, the Ge precursor was fully depleted. Below this region, the Si precursor was added to the plasma, initiating a heterogeneous gas phase surface growth of a Si shell on the Ge nanocrystals.

In the example illustrated in FIG. 3, the gaseous core feed included a mixture of argon (Ar), hydrogen (H₂), and germanium tetrachloride (GeCl₄) vapor. The gaseous core feed entered the reactor vessel through the top of the reactor tube, which in this example was a glass tube with a 1-inch outer diameter. A plasma was generated in the reactor vessel by the application of 50 W radio-frequency power at 13.56 MHz through a pair of copper ring electrodes, coupled through an impedance matching network. The argon and hydrogen flow rates in the gaseous core feed were fixed at 25 and 20 standard cubic centimeters per minute (sccm), respectively. Hydrogen was included in the gaseous core feed to scavenge chlorine produced in the decomposition of GeCl₄. GeCl₄ precursor was selected as the Ge source over GeH₄ due to its lower toxicity and easier handling in laboratory conditions. The partial pressure of GeCl₄ was fixed at 50 mT, 2.5% of the total pressure of the gaseous core feed.

The gaseous shell feed included a 5% silane and argon balance (5% SiH₄/Ar). An additional argon feed was injected into the shell growth region below the powered electrode. The 5% SiH₄/Ar gaseous shell feed was varied over a 0 to 10 sccm flow rate, while the dilution argon was adjusted to maintain a constant total pressure of 2 Torr in the reactor vessel. By adjusting the flow rate of the gaseous shell feed, the concentration of silane introduced into the shell growth region of the plasma was varied from 0-5%. The gaseous shell feed was injected into the shell growth region of the plasma through a stainless steel vacuum fitting with 16 individual 1 mm diameter holes spaced evenly around the circumference of the reactor. The vacuum fitting was grounded and served as a counter electrode. Below this shell region, the Ge/Si nanocrystals were accelerated through an orifice and impacted onto select substrates depending on the desired sample characterization. The prepared samples were kept air-free by transfer through a load-lock system to a N₂ purged glovebox.

The structure of the core/shell nanocrystals was examined by depositing nanocrystals directly onto ultrathin/holey double carbon grids and transferred under argon to an FEI-Titan G2 60-300 equipped with a Gatan Enfinium EEL spectrometer and a Super-X EDS system. To analyze the elemental composition of the core/shell nanocrystals, thick films of Ge/Si were deposited directly onto aluminum-coated Si wafer and examined by SEM-EDX using the Jeol 6500. EDX spectra were considered representative of the nanocrystal if no aluminum was detected. The crystallinity and strain in the Ge/Si nanocrystals deposited onto glass substrates was studied by X-ray diffraction measurements using the Bruker D8 Discover 2D. To assess the surface coverage of the core/shell nanocrystals, thick films were deposited onto aluminum-coated silicon and investigated by reflectance Fourier transform infrared (FTIR) spectroscopy in an oxygen-free, dry N₂-purged glovebox. For comparison, nanocrystals composed of only Si were synthesized from SiCl₄ (2 sccm) in an argon (25 sccm) and hydrogen (20 sccm) gaseous core feed with no gaseous shell feed.

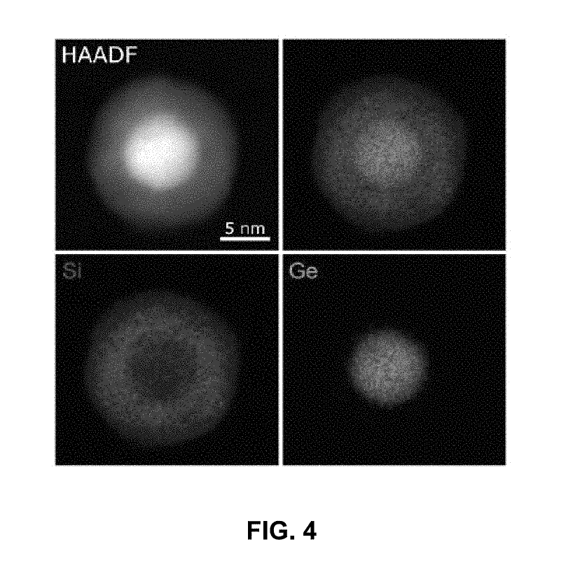

Ge/Si core/shell nanocrystals were synthesized with increasing Si shell thickness while the Ge core nanocrystal size was held constant by fixing the gaseous core feed condition, flow rate, and pressure. The core/shell structure of these nanocrystals is observed in STEM-HAADF imaging, with the elemental distribution revealed by STEM-EDX mapping. FIG. 4 shows EDX spectrum images of the elemental distribution of particles in the Ge/Si core/shell nanocrystals. The EDX spectrum images were acquired at 60 kV with a 25 mrad convergence angle, 200 pA beam current, and 10 minute acquisition times. The presence of lattice fringes through the nanocrystal is indicative of both a crystalline core and shell.

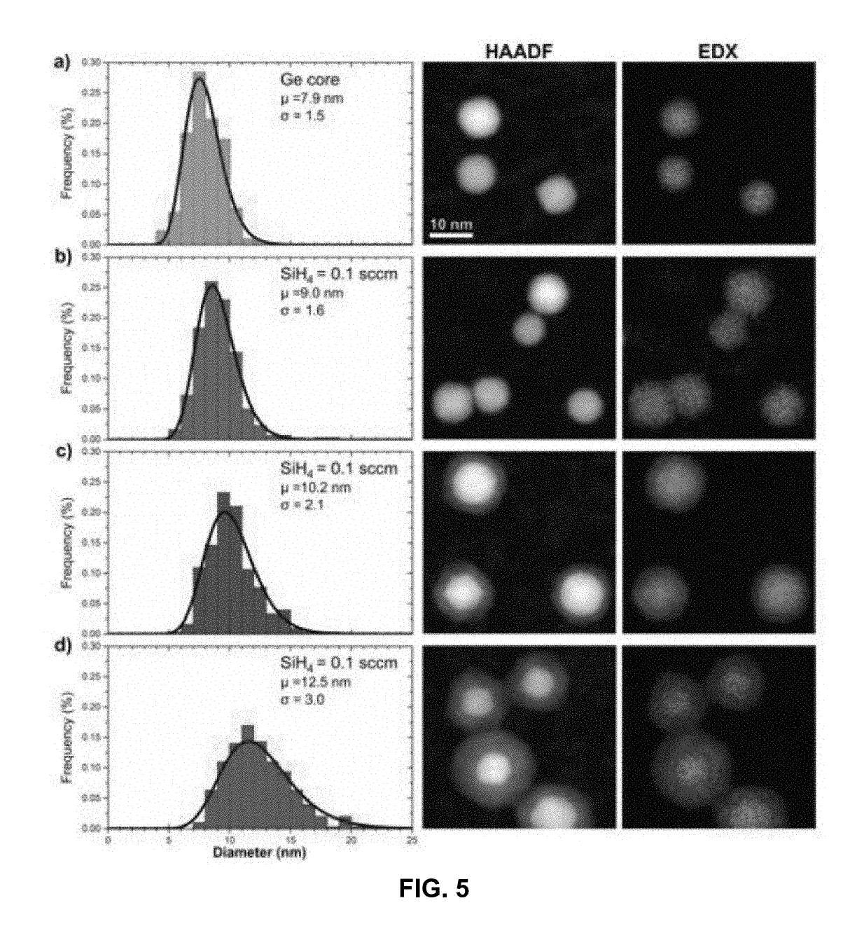

FIG. 5 shows STEM-HAADF images and corresponding size distribution graphs of Ge/Si nanocrystals synthesized at 0, 0.01, 0.02, and 0.05 sccm SiH₄ flowrates in the gaseous shell feed, respectively. For each sample, the diameter of 300 nanocrystals was measured from STEM-HAADF images to determine the nanocrystal size distribution for each SiH₄ flow rate. With no SiH₄ in the gaseous shell feed, uncoated Ge nanocrystals were collected to determine a baseline size dispersity of σ_{g}=1.2. With increasing SiH₄ in the gaseous shell feed, the mean diameter of nanocrystals increase, indicative of controlled shell growth. The size distribution also broadens with increasing shell thickness due to a growing dispersity in shell thickness with increasing SiH₄ flow rate.

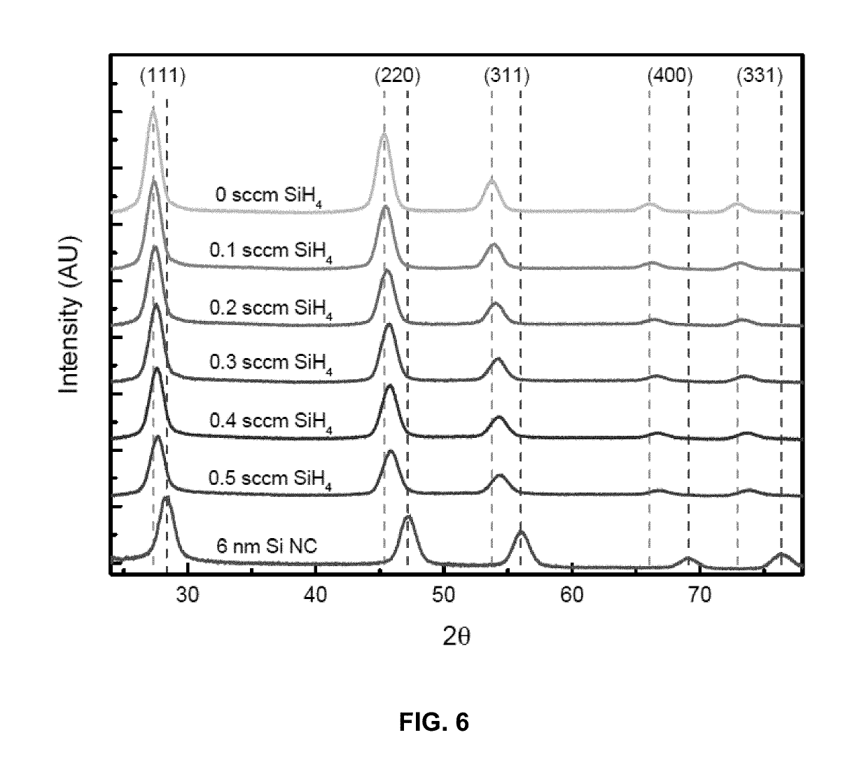

Ge/Si core/shell nanocrystals with increasing Si shell thickness were examined by x-ray diffraction to assess the strain induced by the 4% lattice mismatch between Ge and Si. FIG. 6 is a graph of raw XRD data of Ge/Si core/shell nanocrystals synthesized with an increasing percentage of SiH₄ in the gaseous shell feed. Even for the highest SiH₄ flow rates, the diffraction pattern is consistent with a single phase crystal structure, and consistent with epitaxial shell growth of Si on Ge nanocrystal cores.

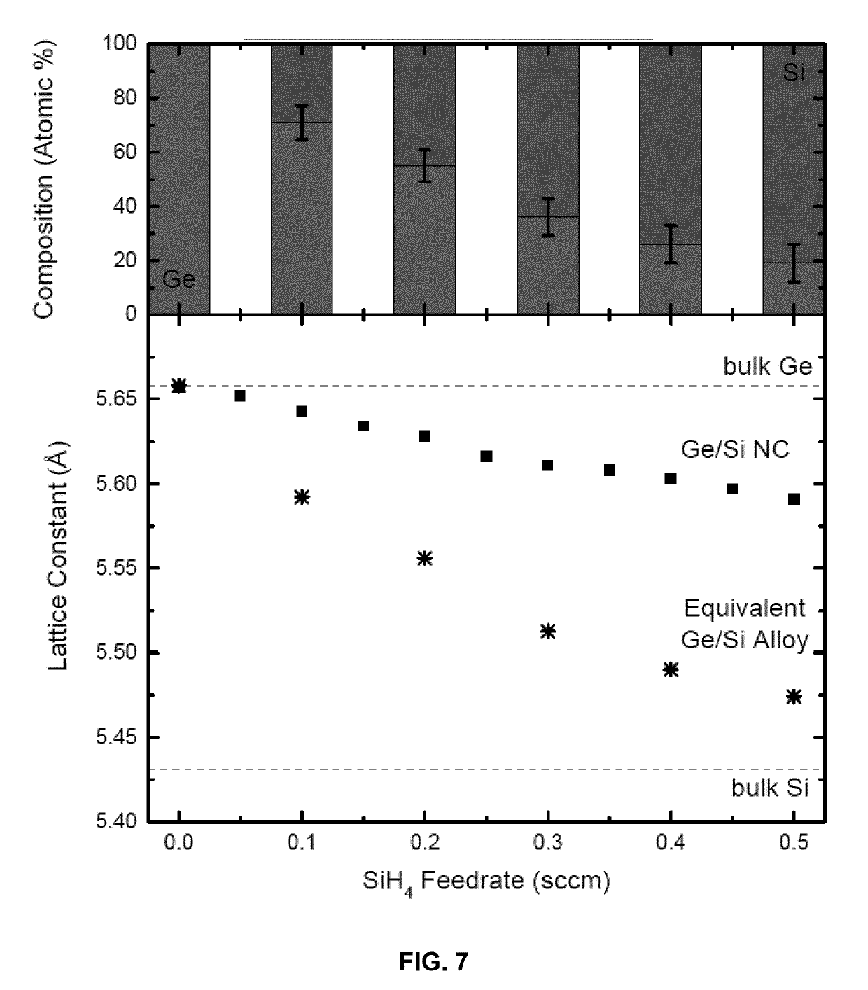

FIG. 7 is a graph of Ge/Si nanocrystal composition and lattice constant for various feed rates of SiH₄. Diffraction peaks of the nanocrystals may shift to larger 2θ values relative to bulk Ge, indicative of lattice contraction. 0D and 1D nanostructures may be more accommodating of strain than their 2D planar counterparts due to a large radius of curvature and ability of both core and shell to accept strain, as observed by compression of the Ge nanocrystal core. A 2θ-dependent broadening of the diffraction peaks may be observed, which may be attributed to a dispersity in strain resulting from the shell thickness dispersity, in agreement with the size distributions observed in STEM. The ensemble composition of these samples was determined by STEM-EDX. Surface species such as chlorine from the GeCl₄ precursor and oxygen from exposure to air during transfer were neglected in calculating nanocrystal composition.

These estimates, along with STEM-EDX maps, may indicate a strained core/shell structure. There may also be some degree of interdiffusion of Ge and Si occurring at the surface of the core/shell nanocrystals. It is possible that the diffraction patterns are a combined product of strain and alloying.

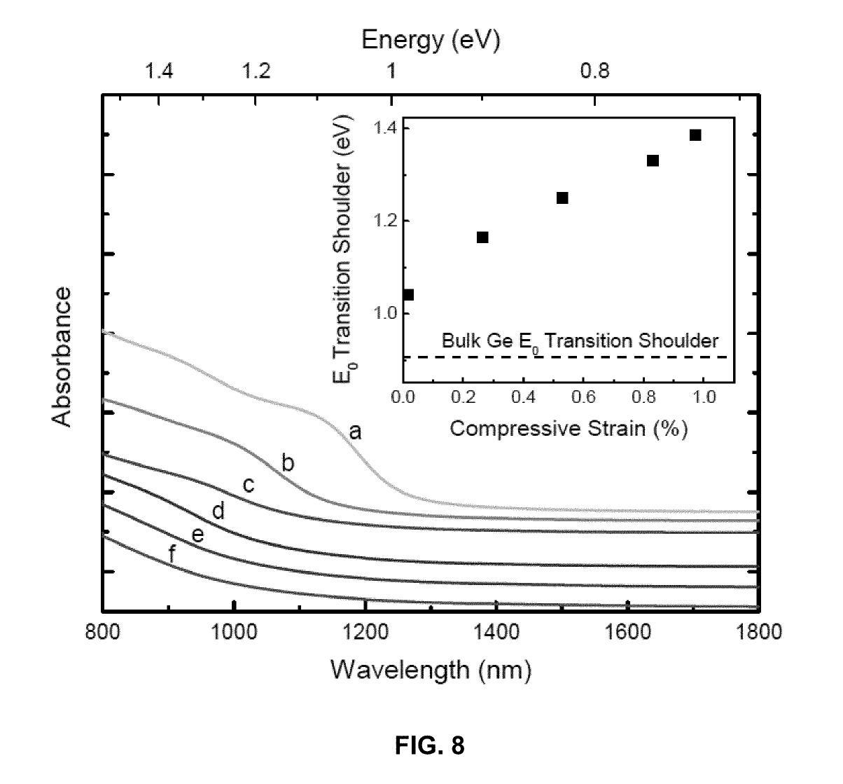

The ability to tune optical properties with nanocrystal dimensions is an important feature and application of nanocrystals in optoelectronics. FIG. 8 is an inset graph of absorption transition as a function of compressive strain induced by increasing shell thickness for Ge nanocrystal cores, and an outset graph of a change in absorption spectra for various layers of shell thickness of Ge/Si nanocrystals. The effect of Si shell growth on Ge nanocrystal band structure was probed through thick film extinction measurements. Bulk Ge may exhibit an indirect Γ-L transition of 0.67 eV followed by strong absorption onset at 0.80 eV from the direct Γ transition. This direct feature may be observed experimentally as a shoulder in the NIR extinction spectrum of Ge nanocrystal cores around 1140 nm (1.1 eV), which is blueshifted from the bulk E₀ transition shoulder due to quantum confinement effects. With increasing Si, the E₀ shoulder in the extinction spectra of the Ge/Si nanocrystals blue shifts, indicative of a widening of the Γ transition. The energies of these shoulders are determined by finding the inflection point in the first derivative of the extinction spectrum. An explanation of the widening of the F point may be the strain induced modulation of the Ge band structure. The effect observed here may be the inverse of the narrowing of the direct Γ transition due to tensile-strained Ge. The relationship between E₀ transition energy and strain is plotted in the inset of FIG. 8, where the change in lattice constant may be due to strain. For samples synthesized at the highest SiH₄ feed rates, the polydispersity of size and strain in these samples may blur the transition shoulder.

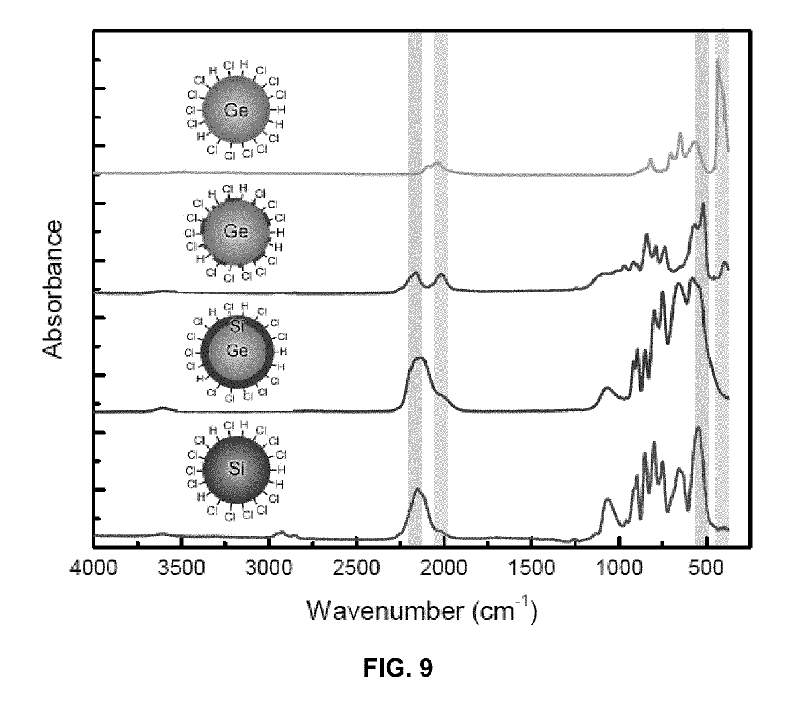

The Ge/Si nanocrystal surface was investigated using diffuse reflectance FTIR to probe surface bonds. FIG. 9 is a graph of wavenumber and mid-infrared absorbance for Ge nanocrystals, Ge/Si partially coated nanocrystals, Ge/Si fully coated nanocrystals, and Si nanocrystals. Absorbance spectrum of the uncoated Ge nanocrystals exhibits a dominant feature around 412 cm⁻¹, which may correspond to a stretching mode of Ge-Clₓ surface bonds, while a small broad peak at 2100 cm⁻¹ may be attributable to the stretching mode of Ge-Hₓ surface bonds. In a spectrum collected to Si nanocrystals synthesized under identical nonthermal plasma conditions from SiCl₄, the Si-Clₓ and Si-Hₓ stretch features shifted to 575 cm⁻¹ and 2200 cm⁻¹, respectively. An absorbance spectrum representing fully coated Ge/Si nanocrystals has an absence of Ge-Cl and Ge-H modes which may be evidence of complete Si shell coverage of the Ge core. An absorbance spectrum representing partially coated Ge/Si nanocrystals has Ge-Cl and Ge-H modes that are still detectable. The partially coated Ge/Si nanocrystals were produced by increasing the separation of the electrode from the SiH₄ injection point to 10 cm such that the plasma density in the shell formation region of the reactor vessel was significantly suppressed.

The Si-Cl bonds on the surface of the nanocrystals may allow for dispersal in a variety of solvents, including 2-butanone and 1,2-dichlorobenzene, or for subsequent solution-phase functionalization via Grignard reagents for dispersal in non-polar solvents. Transfer to solution may allow for nanocrystal integration into optoelectronic devices through colloidal processing, such as printing, spin-casting, and dip-coating, with or without the use of insulating ligands.

Generally, nonthermal plasma reactors may exhibit a high degree of control over nanocrystal core size by varying gas flow rates, reactor pressure, and input RF power. Additionally, as demonstrated above, shell thickness in core/shell nanocrystals may be affected by several controllable experimental conditions in the plasma afterglow, including: SiH₄ concentration, set by the gaseous shell feed flow rate; plasma electron density in the plasma afterglow, set by the input power and electrode height; core Ge nanocrystal size and concentration, set by the gaseous core feed flow rate and conditions; and nanocrystal residence time through the plasma afterglow, set by total gas flow rate and pressure in the reactor vessel.

For this experiment, shell thickness was controlled for using variation in shell precursor (SiH₄) concentration, with all other factors carefully controlled. Plasma density was held constant by the consistent application of 50 W RF power and by holding the powered electrode height fixed at 6 cm distance away from the point of gaseous shell precursor injection. Ge nanocrystal core size and concentration were fixed by holding gaseous core feed flow rates constant. Nanocrystal residence time was fixed by keeping the total gas flow rate fixed at 55 sccm and pressure fixed at 2 Torr. For a nanocrystal collection rate of 12 mg/hr, an estimated nanocrystal concentration may have been about 6×10⁹ nanocrystals cm⁻³.

The effect of the experimental conditions on shell growth may be understand, for example, by aerosol collision growth models. The collision rate, R, between Ge nanocrystal cores (index 1) and silane radicals, SiHₓ*, (index 2) may be described by Equation 1 below:

R=β(a₁, a₂)n₂n₂ (Equation 1)

where the collision kernel, β, is dependent on particle radius, a. While SiH₄ molecules with a concentration up to 3×10¹⁴ cm⁻³ may be the dominant gas species early in shell growth, silane radicals (SiH₂* and SiH₃*), may be considered the dominant growth species as the sticking coefficient, γ, is orders of magnitude greater than molecular silane. The shell growth process may be represented as an in-flight plasma-enhanced chemical vapor deposition (PECVD) process.

For heterogeneous surface growth of SiHₓ* to be the dominant reaction over Si nucleation, the concentration of silane radicals may remain below 2×10¹¹ cm⁻³. Silane radicals are generated in the plasma by electron impact dissociation, hydrogen abstraction, or dissociative attachment. The concentration of these reactive species may be determined by the rate of generation, which may be dependent on the electron density and temperature, and the rate of consumption, which may be dependent on collisions with the Ge nanocrystal cores and self-nucleation.

Various examples have been described. These and other examples are within the scope of the following claims.

What is claimed is:

1. A method comprising:
powering, using a plasma source, a nonthermal plasma reactor to form a plasma in a core formation region and a shell formation region of the nonthermal plasma reactor, wherein the shell formation region is downstream of the core formation region;
introducing, upstream of the core formation region, gaseous core precursors, wherein the gaseous core precursors form negatively-charged core nanoparticles from the gaseous core precursors in the core formation region of the nonthermal plasma reactor; and
introducing, to the plasma downstream of the core formation region, gaseous shell precursors, wherein the gaseous shell precursors form shells on the core nanoparticles in the shell formation region of the nonthermal plasma reactor to produce core/shell nanoparticles.

2. The method of claim 1, further comprising at least one of introducing a core inert gas with the gaseous core precursors or a shell inert gas with the gaseous shell precursors.

3. The method of claim 2, wherein the at least one of the core inert gas or the shell inert gas comprises at least one of argon or helium.

4. The method of claim 2, wherein the core inert gas and the shell inert gas are the same gas.

5. The method of claim 1, wherein the plasma source comprises one or more electrodes and a power source.

6. The method of claim 5, wherein the power source is a radiofrequency power source.

7. The method of claim 1, further comprising introducing, to the nonthermal plasma reactor, gaseous dopant precursors.

8. The method of claim 7, wherein the gaseous dopant precursors include at least one of boron or phosphorus.

9. The method of claim 1, wherein the gaseous core precursors or gaseous shell precursors include at least one of group IV elements, metals, metal oxides, metal nitrides, or metal sulfides.

10. The method of claim 1, further comprising collecting the core/shell nanoparticles downstream of the shell formation region.

11. The method of claim 10, wherein collecting the core/shell nanoparticles comprises:
forming a beam of the core/shell nanoparticles; and
depositing the core/shell nanoparticles on a substrate to form a thin film.

12. The method of claim 11, wherein the plasma includes a plasma density greater than 10⁹ electrons·cm⁻³ at a location of the nonthermal plasma reactor at which the gaseous core precursors are introduced.

13. The method of claim 1, wherein the core nanoparticles are core nanocrystals.

14. An apparatus comprising:
a nonthermal plasma reactor vessel comprising;
a core formation region; and
a shell formation region downstream of the core formation region;
a gaseous core precursor inlet, upstream of the core formation region, configured to introduce gaseous core precursors to the reactor vessel;
a gaseous shell precursor inlet, downstream of the core formation region and upstream of the shell formation region, configured to introduce gaseous shell precursors to the reactor vessel;
a plasma source configured to produce a plasma in the core formation region and the shell formation region, wherein the gaseous core precursors form negatively-charged core nanoparticles from the gaseous core precursors in the core formation region of the reactor vessel, and where the gaseous shell precursors from shells on the core nanoparticles in the shell formation region of the reactor vessel.

15. The apparatus of claim 14, wherein the gaseous core precursor inlet is further configured to introduce a core inert gas, or wherein the gaseous shell precursor inlet is further configured to introduce a shell inert gas, or both.

16. The apparatus of claim 15, wherein at least one of the core inert gas or the shell inert gas comprises at least one of argon or helium.

17. The apparatus of claim 15, wherein the core inert gas and the shell inert gas are the same gas.

18. The apparatus of claim 14, wherein the plasma source comprises a power source electrically coupled to one or more electrodes.

19. The apparatus of claim 18, wherein the power source is a radiofrequency power source.

20. The apparatus of claim 14, wherein the gaseous core precursor inlet or the gaseous shell precursor inlet is further configured to introduce gaseous dopant precursors to the reactor vessel.

21. The apparatus of claim 20, wherein the gaseous dopant precursors include at least one of boron or phosphorus.

22. The apparatus of claim 14, wherein the gaseous core precursors or gaseous shell precursors include at least one of group IV elements, metals, metal oxides, metal nitrides, or metal sulfides.

23. The apparatus of claim 14, further comprising a nanoparticle collection unit downstream of the shell formation region.

24. The apparatus of claim 23, wherein the nanoparticle collection unit comprises a nanoparticle orifice and a substrate, wherein the nanoparticle orifice is configured to form a nanoparticle beam that deposits a thin film on the substrate.

25. The apparatus of claim 14, wherein the plasma includes a plasma density greater than 10⁹ electrons·cm⁻³ at the gaseous core precursor inlet.

26. The apparatus of claim 14, wherein the core nanoparticles are core nanocrystals.

27. A system comprising:
a controller configured to:
control a plasma source to power a nonthermal plasma reactor to form a plasma in a core formation region and a shell formation region of the nonthermal plasma reactor, wherein the shell formation region is downstream of the core formation region;
control a gaseous core precursor inlet, upstream of the core formation region, to introduce gaseous core precursors to the nonthermal plasma reactor, wherein the gaseous core precursors form negatively-charged core nanoparticles from the gaseous core precursors in the core formation region of the nonthermal plasma reactor; and
control a gaseous shell precursor inlet, downstream of the core formation region and upstream of the shell formation region, to introduce gaseous shell precursors to the nonthermal plasma reactor, wherein the gaseous shell precursors form shells on the core nanoparticles in the shell formation region of the nonthermal plasma reactor.

28. A computer-readable storage medium storing instructions that, when executed, cause a processor to:
power, using a plasma source, a nonthermal plasma reactor to form a plasma in a core formation region and a shell formation region of the nonthermal plasma reactor, wherein the shell formation region is downstream of the core formation region;
introduce, upstream of the core formation region, gaseous core precursors, wherein the gaseous core precursors form negatively-charged core nanoparticles from the gaseous core precursors in the core formation region of the nonthermal plasma reactor; and
introduce, to the plasma downstream of the core formation region, gaseous shell precursors, wherein the gaseous shell precursors form shells on the core nanoparticles in the shell formation region of the nonthermal plasma reactor.
